(19) United States
(12) Patent Application Publication
(10) Pub. No.: US 2017/0263897 A1
(43) Pub. Date: Sep. 14, 2017

(54) METHOD FOR PREPARING UNEVEN PARTICLE LAYER, ORGANIC LIGHT EMITTING DIODE DEVICE AND DISPLAY DEVICE

(71) Applicants: BOE TECHNOLOGY GROUP CO., LTD., Beijijng (CN); HEFEI BOE OPTOELECTRONICS TECHNOLOGY CO., LTD., Hefei, Anhui (CN)

(72) Inventors: Yuanhui GUO, Beijing (CN); Yuansheng ZANG, Beijing (CN); Zhi LIU, Beijing (CN); Xiaohe LI, Beijing (CN); Hui WANG, Beijing (CN)

(21) Appl. No.: 15/127,460

(22) PCT Filed: Feb. 18, 2016
(86) PCT No.: PCT/CN2016/073987

§ 371 Date: Sep. 20, 2016

(30) Foreign Application Priority Data
Sep. 17, 2015 (CN) 201510596057.7

(51) Int. Cl. H01L 51/52; C09D 133/10; C09D 125/06; H01L 51/56; C09D 7/12

(52) U.S. Cl. CPC H01L 51/5275; H01L 51/56; C09D 7/1275; C09D 125/06; C09D 133/10; H01L 2251/5369; H01L 2251/556; H01L 51/0035

(57) ABSTRACT

The present invention provides a method for preparing an uneven particle layer, an organic light emitting diode device and a display device. The method for preparing an uneven particle layer includes the following steps: forming a nanoparticle layer on a substrate; heating the substrate to fuse nanoparticles that are in contact with the substrate, whereas the nanoparticles on the surface keep a solid state; and cooling the substrate to form a nanoparticle layer with an uneven surface. The method of the present invention is simple in process, and industrial production is easy to achieve. The substrate including the uneven particle layer is applied to the OLED device, so the propagation direction of rays can be changed so as to avoid total reflection on an interface and thus improve the light extraction efficiency of the OLED device. The OLED device prepared in the present invention is suitable for various display devices.

### FIELD OF THE INVENTION

The present invention relates to the field of display technology, and particularly relates to a method for preparing an uneven particle layer, an organic light emitting diode device and a display device comprising the uneven particle layer.

### BACKGROUND OF THE INVENTION

An OLED (Organic Light Emitting Diode) device simultaneously has the excellent characteristics of being self-luminous, free of backlight, high in contrast, small in thickness, wide in viewing angle, high in response speed, available for flexible panels, wide in using temperature range, simple in constructing and manufacturing procedures and the like, thereby being deemed as an emerging technology of the next-generation flat display devices.

The existing OLED has a structure as shown in schematic diagrams FIG. 1 and FIG. 2, and it includes a cathode, an organic light emitting layer, an anode and a glass substrate.

The inventor finds that the prior art at least has the following problems: when a photon emitted by the organic light emitting layer irradiates the air layer, the photon is reflected and refracted on an interface of an incident medium (the incident medium in FIG. 1 is a glass substrate, and the incident in FIG. 2 medium is a semitransparent cathode) and the air, and an incidence angle and a refraction angle meet a relational expression: n₁·sin θ₁=n₂·sin θ₂, wherein n₁ represents a refractive index of the incident medium, n₂ represents a refractive index of the air. When the incidence angle is greater than or equal to a critical angle, total reflection occurs, and rays cannot be emitted to the air. In FIG. 1 and FIG. 2, rays a and b are emitted into the air after being refracted, while rays c and d perform total reflection on the interface and thus cannot escape from the surface of the glass substrate, since the incidence angle thereof is greater than or equal to the critical angle, namely an “escape cone” of a certain angle exists, which reduces a light extraction efficiency of the OLED device.

### SUMMARY OF THE INVENTION

In view of the above problem of low light extraction efficiency of the existing OLED device, the present invention provides a method for preparing an uneven particle layer, an organic light emitting diode device and a display device containing the uneven particle layer.

The technical solution for solving the technical problem in the present invention is as follows:

a method for preparing an uneven particle layer including the following steps:

forming a nanoparticle layer on a substrate;

heating the substrate to fuse nanoparticles that are in contact with the substrate, whereas the nanoparticles on the surface keep a solid state; and

cooling the substrate to form a nanoparticle layer with an uneven surface.

Preferably, the step of forming a nanoparticle layer on a substrate is to coat a mixed solution of the nanoparticles which includes the nanoparticles, a solvent used for dispersing the nanoparticles and a dispersant, oil the substrate.

Preferably, the nanoparticle layer is composed of a single layer of nanoparticles.

Preferably, the step of heating the substrate is carried out on a side of the substrate with no nanoparticle layer.

Preferably, the nanoparticle layer is made of a transparent polymer material.

Preferably, the transparent polymer material includes polystyrene and/or polymethacrylate.

Preferably, the glass transition temperature of the transparent polymer material is T₁, and the heating temperature is T₁ to T₁+50° C.

Preferably, the heating time is 1-20 min.

Preferably, the shape of the nanoparticles is a sphere.

Preferably, the particle size of the nanoparticles is 400-700 nm.

Preferably, the thickness of the uneven particle layer is less than 1000 nm.

Preferably, before coating the mixed solution of the nanoparticles, an electrode is arranged on the substrate in advance.

The present invention further provides an OLED device, including a substrate, an anode, an organic light emitting layer and a cathode, wherein the substrate includes an uneven particle layer prepared according to the above method.

The present invention further provides a display device, including the aforementioned OLED device.

According to the method for preparing the uneven particle layer in the present invention, only coating and heating steps need to be added, so the method is simple and industrial production is easy to achieve. A level of the unevenness of the surface of the uneven particle layer prepared by the method is uniform, and the periodicity thereof is good. The substrate including the uneven nanoparticle layer is applied to the OLED device, the performance of the device is stable, and the propagation direction of rays from the organic light emitting layer of the OILED device can be changed to avoid total reflection on an interface so as to emit more light into the air, thereby improving the light extraction efficiency of the OLED device and improving the brightness and the viewing angle of the OLED device. The OLED device prepared by the method in the present invention is suitable for various display devices.

### BRIEF DESCRIPTION OF THE DRAWINGS

FIG. 1 is a structural schematic diagram of an existing OLED device;

FIG. 2 is a structural schematic diagram of another existing OLED device;

FIG. 3 is a schematic diagram of a method for preparing an uneven particle layer according to the present invention;

FIG. 4 is a structural schematic diagram of an OLED device according to the third embodiment of the present invention;

FIG. 5 is a schematic diagram of light emission of the OLED device according to the third embodiment of the present invention;

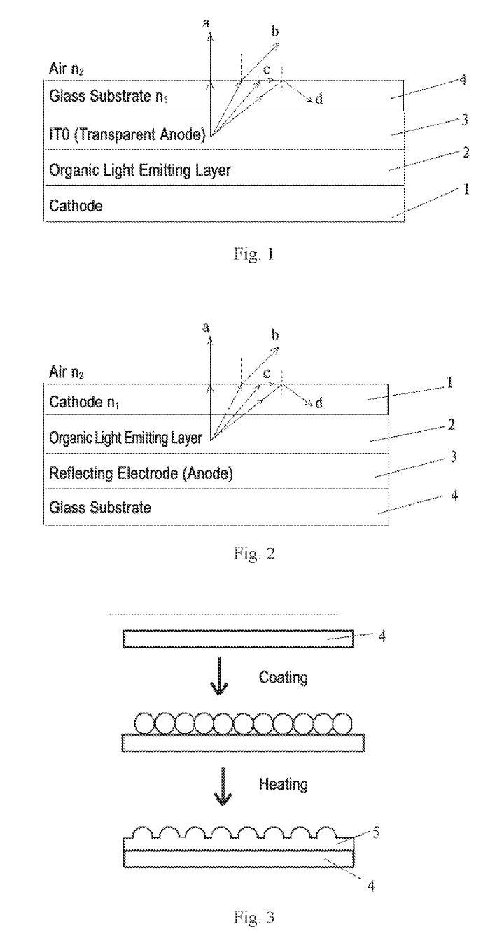

### DESCRIPTION OF THE PREFERRED EMBODIMENT

In order that those skilled in the art can better understand the technical solutions of the present invention, a further detailed description of the present invention will be given below in combination with the accompany drawings and specific embodiments.

According to an embodiment of the present invention, a method for preparing an uneven particle layer is provided, including the following steps:

forming a nanoparticle layer on a substrate;

heating the substrate to fuse nanoparticles that are in contact with the substrate, whereas the nanoparticles on the surface keep a solid state; and

cooling the substrate to form a nanoparticle layer with an uneven surface.

As show in FIG. 3, the method specifically includes the following steps:

S1, forming a nanoparticle layer on a substrate, which is realized by:

mixing nanoparticles with a solvent used for dispersing the nanoparticles and a dispersant, to form a mixed solution of the nanoparticles; and then, coating the mixed solution of the nanoparticles on the substrate 4.

The nanoparticles can be made of an inorganic material or an organic material. Preferably, the nanoparticles are made of a transparent polymer material. The transparent polymer material includes, but not limited to, polystyrene, polymethylacrylic acid, etc.

As the transparent polymer material is adopted, when the substrate 4 with the uneven particle layer is applied to an OLED device, the light extraction efficiency can be improved.

Preferably, the nanoparticles can be polystyrene and/or polymethacrylate. Preferably, the nanoparticle layer is composed of a single layer of nanoparticles.

The nanoparticles are mixed with the solvent and the dispersant, and the nanoparticles can be uniformly dispersed by the solvent and the dispersant, so as to obtain a nanoparticle layer with a uniform thickness. The obtained nanoparticle layer can reduce total reflection and improve the light extraction efficiency of an OLED device. Particularly, the dispersant is helpful to improve the arrangement of the nanoparticles on the surface of the substrate 4 and prevent the accumulation of the nanoparticles, so it is helpful to form a single layer of nanoparticles.

Those skilled in the art can select a suitable solvent and a suitable dispersant according to the type of the specifically selected nanoparticles. When the nanoparticles are polystyrene, methanol or toluene and the like organic solvents can be adopted; and when the nanoparticles are polymethacrylate, chloroform, acetic acid, ethyl acetate, acetone and the like organic solvents can be adopted. Preferably, a solvent with strong volatility is adopted. Those skilled in the art can select the dispersant adaptive to the nanoparticles according to experience, for example, PVP (polyvinyl pyrrolidone), etc.

Preferably, the shape of the nanoparticles is a sphere.

When the shape of the nanoparticles is a sphere, the unevenness of the surface of the uneven particle layer 5 prepared by the method is uniform, and the periodicity thereof is good. When the uneven particle layer is applied to an OLED device, the rays do not perform total reflection on the spherical surfaces, and the emission direction of the rays is the same as the normal direction, as shown in FIG. 5.

Preferably, the particle size of the nanoparticles is 400-700 nm.

That is to say, if the particle size of the nanoparticles is too large or too small, it is unbeneficial to controlling the thickness of the formed uneven particle layer 5, and when the particle size of the nanoparticles is 400-700 nm, the coating operation and the heating formation operation are easy to carry out.

The mixed solution of the nanoparticles can he coated on the substrate 4 by adopting a conventional coating method. Preferably a spin coating mode is applied by which it can be guaranteed that a film layer with a uniform thickness is formed by the mixed solution on the substrate 4 and a monomolecular layer of polystyrene nanoparticles is formed.

S2, heating the substrate 4 to fuse nanoparticles that are in contact with the substrate, whereas the nanoparticles on the surface keep a solid state;

Preferably, the heating is carried out on a side of the substrate 4 not coated with nanoparticles. That is to say, the back surface of the substrate 4 is heated, by which the nanoparticles on the substrate 4 are heated, so the molecular motion thereof accelerates and a part of nanoparticles are gradually fused, thereby changing the surface morphology of the nanoparticles so as to form an uneven surface.

Preferably, the heating time is 1-20 min, preferably 1-10 min and more preferably 2-5 min. Those skilled in the art can change the specific heating time for different nanoparticle materials according to experience,

Preferably, if the glass transition temperature of the transparent polymer is T₁, the heating temperature is T₁ to T₁+50° C., preferably T₁ to T₁+30° C., and more preferably T₁ to T₁+15° C., That is, the heating temperature is between the glass transition temperature of the transparent polymer and the glass transition temperature thereof plus 50° C. Upon exceeding the glass transition temperature, polymer macromolecules start to be unfastened and are gradually fused. According to the time-temperature equivalence principle, the heating time necessary for a higher heating temperature is shorter, and on the contrary, if the heating temperature is lower, the necessary heating time is longer. Specifically, if the glass transition temperature of the polystyrene nanoparticles is 80° C., then the heating temperature is not greater than 130° C. and is between 80-130° C. The heating time is longer at 80° C., and the heating time is shorter at 130° C.

S3, cooling the substrate 4to form a nanoparticle layer 5 with an uneven surface

Preferably, the thickness of the uneven particle layer 5 is less than 1000 nm, so as to guarantee better performance of an OLED device prepared by the method.

Preferably, before coating the mixed solution of the nanoparticles, an anode 3 is arranged on the substrate 4. In such case, the mixed solution of the nanoparticles coated on the substrate 4 is actually coated on the anode 3.

In another specific embodiment of the present invention, an OLED device is provided, including a substrate, an anode, an organic light emitting layer and a cathode, wherein the substrate is prepared according to the above method and includes an uneven particle layer. Apparently, the OLED device in the specific embodiment can be in a form of top light emission and can also in the form of bottom light emission.

Another solution of the present invention provides a display device, including the aforementioned OLED device. The display device can be any product or component having a display function, such as electronic paper, a mobile phone, a tablet computer, a television, a display, a notebook computer, a digital picture frame, a navigator, etc.

### EXAMPLE 1

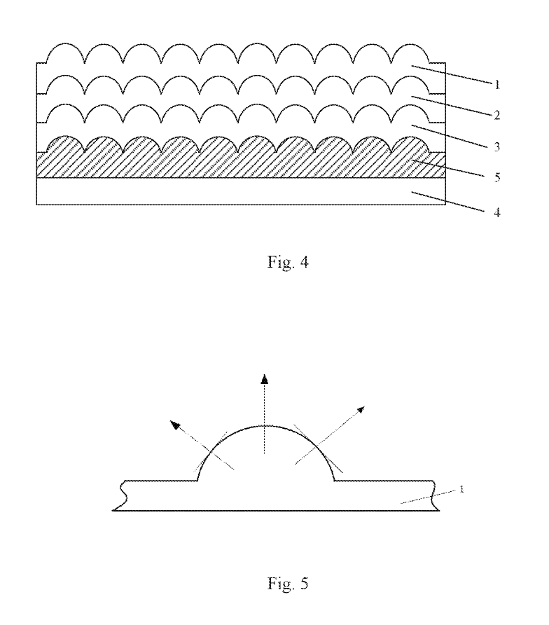

As shown in FIG. 4, an OLED device A is provided, including a substrate 4, an anode 3, an organic light emitting layer 2 and a cathode 1, wherein the substrate 4 includes an uneven particle layer prepared according to the above method.

The nanoparticles are polystyrene nanoparticles with a particle size of 600 )nm, the solvent is methanol, and the dispersant is polyvinylpyrrolidone (PVP).

The substrate 4 is made of a polyethylene terephthalate (PET) material. The anode 3 is made of aluminum, and the thickness of the anode 3 is 150 nm.

The specific preparation steps include:

adding the polystyrene nanoparticles with a particle size of 600 nm and the dispersant PVP into the solvent methanol, and mixing them uniformly to form a mixed solution;

coating the mixed solution on the PET substrate 4;

heating a surface not coated with nanoparticle of the substrate 4 at 110° C. for 2 min to fuse the nanoparticles close to the substrate 4, and keep the nanoparticles away from the substrate 4 in a solid state to form a hemisphere;

cooling the substrate 4 to form an uneven particle layer 5 on the substrate;

forming the anode 3 on the substrate 4 after the above steps are completed;

forming the organic light emitting layer 2 on the substrate 4 after the above steps are completed; and

forming the cathode 1 on the substrate 4 after the above steps are completed.

### COMPARATIVE EXAMPLE 1

An OLED device B is manufactured by the same method as Example 1, and the difference lies in that no uneven particle layer 5 is formed.

A brightness test is carried out on the OLED device A and the OLED device B. Under the same voltage, the brightness of the OLED device A is 1.2 times as large as the brightness of the OLED device B at a front viewing angle (θ=0°, Φ=0°), and the brightness of the device A is 1.5 times as large as the brightness of the device B at a side viewing angle (θ=45°, φ=45°).

### EXAMPLE 2

As shown in FIG. 4, an OLED device C is provided, including a substrate 4, an anode 3, an organic light emitting layer 2 and a cathode 1, wherein the substrate 4 includes an uneven particle layer prepared according to the above method.

The nanoparticles are polymethylacrylic acid nanoparticles with a particle size of 600 nm, the solvent is methanol, and the dispersant is PVP.

The substrate 4 is made of a glass material, the anode 3 is made of aluminum, and the thickness of the anode 3 is 150 nm.

The specific preparation steps include:

adding the polymethylacrylic acid nanoparticles with a particle size of 600 nm and the dispersant PVP into the solvent methanol, and mixing them uniformly to form a mixed solution;

coating the mixed solution on the PET substrate 4;

heating a surface not coated with nanoparticle of the substrate 4 at 120° C. for 2 min to fuse the nanoparticles close to the substrate 4, and keep the nanoparticles away from the substrate 4 in a solid state to form a hemisphere;

cooling the substrate 4 to form an uneven particle layer 5 on the substrate;

forming the anode 3 on the substrate 4 after the above steps are completed;

forming the organic light emitting layer 2 on the substrate 4 after the above steps are completed; and

forming the cathode 1 on the substrate 4 after the above steps are completed.

### COMPARATIVE EXAMPLE 2

An OLED device D is manufactured by the same method as the Example 2, and the difference lies in that no uneven particle layer 5 is formed.

A brightness test is carried out on the OLED device C and the OLED device D. Under the same voltage, the brightness of the OLED device A is 1.3 times as large as the brightness of the OLED device B at a front viewing angle (θ=0°, φ=0°), and the brightness of the device A is 1.6 times as large as the brightness of the device B at a side viewing angle (θ=45°, φ=45°).

It can be understood that, the above embodiments are merely exemplary embodiments used for illustrating the principle of the present invention, but the present invention is not limited hereto. Those of ordinary skill in the art can make a variety of modifications and improvements without departing from the spirit and essence of the present invention, and these modifications and improvements are deemed as the protection scope of the present invention.

1. A method for preparing an uneven particle layer, comprising the following steps:
forming a nanoparticle layer on a substrate;
heating the substrate to fuse nanoparticles that are in contact with the substrate, whereas the nanoparticles on the most surface keep a solid state; and
cooling the substrate to form a nanoparticle layer with an uneven surface.

2. The method for preparing the uneven particle layer according to claim 1, wherein the step of forming a nanoparticle layer on the substrate is to coat a mixed solution of the nanoparticles comprising the nanoparticles, a solvent used for dispersing the nanoparticles and a dispersant on the substrate.

3. The method for preparing the uneven particle layer according to claim 1, wherein the step of heating the substrate is carried out on a side of the substrate with no nanoparticle layer.

4. The method for preparing the uneven particle layer according to claim 1, wherein the nanoparticle layer is made of a transparent polymer material.

5. The method for preparing the uneven particle layer according to claim 4, wherein the transparent polymer material comprises polystyrene and/or polymethacrylate.

6. The method for preparing the uneven particle layer according to claim 4, wherein the glass transition temperature of the transparent polymer material is T₁, and the heating temperature is T₁ to T₁+50° C.

7. The method for preparing the uneven particle layer according to claim 6, wherein the heating time is 1-20 min.

8. The method for preparing the uneven particle layer according to claim 1, wherein the nanoparticle has a shape of sphere.

9. The method for preparing the uneven particle layer according to claim 1, wherein the nanoparticle has a particle size of 400-700 nm.

10. The method for preparing the uneven particle layer according to claim 1, wherein the uneven particle layer has a thickness of less than 1000 nm.

11. The method for preparing the uneven particle layer according to claim 1, wherein the nanoparticle layer is composed of a single layer of nanoparticles.

12. The method for preparing the uneven particle layer according to claim 2, wherein before coating the mixed solution of the nanoparticles, an electrode is arranged on the substrate.

13. An organic light emitting diode device, comprising a substrate, an anode, an organic light emitting layer and a cathode, wherein the OLED device further comprises an uneven particle layer prepared by the method of claim 1.

14. A display device, comprising the OLED device of claim 13.
